(19) United States
(12) Patent Application Publication
(10) Pub. No.: US 2023/0006420 A1
(43) Pub. Date: Jan. 5, 2023

(54) GROWTH DEFECT REDUCTION AT GRATING TRANSITION

(71) Applicant: ROCKLEY PHOTONICS LIMITED, Altrincham, Cheshire (GB)

(72) Inventor: Charles Su-chang TSAI, Pasadena, CA (US)

(21) Appl. No.: 17/756,808

(22) PCT Filed: Dec. 9, 2020
(86) PCT No.: PCT/EP2020/085339

§ 371 Date: Jun. 2, 2022

Related U.S. Application Data
(60) Provisional application No. 62/945,751, filed on Dec. 9, 2019.

(51) Int. Cl. H01S 5/12; H01S 5/22; H01S 5/343

(52) U.S. Cl. CPC H01S 5/1203; H01S 5/22; H01S 5/34313

(57) ABSTRACT

A semiconductor device. In some embodiments, the semiconductor device includes: a first layer having a first region and a second region, the first region being corrugated with a plurality of corrugations, the second region being uncorrugated. A first cycle of the corrugations may have a first duty cycle and a second cycle of the corrugations may have a second duty cycle, the second cycle being between the first cycle and the second region, and the second duty cycle being between the first duty cycle and the duty cycle of the second region.

### FIELD

One or more aspects of embodiments according to the present disclosure relate to gratings, and more particularly to a grating for a laser, and a method for fabrication thereof.

### BACKGROUND

Growth defects in the active region of a DFB laser may degrade its reliability. When a DFB laser is fabricated with a grating on the n-side of the laser junction, below the active region, a smooth planarization of the grating surface as close to horizontal as possible may help to reduce growth defects in the quantum well active region. In a DFB laser that incorporates a partially-corrugated grating with an abrupt boundary between the corrugated region and the grating-free region, the abrupt boundary may result in a sharp slope that may cause a concentrated density of growth defects.

Thus, there is a need for an improved design for a DFB laser with a partially corrugated grating.

### SUMMARY

According to an embodiment of the present disclosure, there is provided a semiconductor device, including: a first layer having a first region and a second region, the first region being corrugated with a plurality of corrugations, the second region being uncorrugated, a first cycle of the corrugations having a first duty cycle, a second cycle of the corrugations having a second duty cycle, the second cycle being between the first cycle and the second region, the second duty cycle being between the first duty cycle and the duty cycle of the second region.

In some embodiments, the semiconductor device includes a distributed feedback laser, the distributed feedback laser including: the first region of the first layer, and the second region of the first layer.

In some embodiments, the semiconductor device further includes a plurality of quantum well layers on the first layer.

In some embodiments, the semiconductor device further includes a plurality of quantum well layers under the first layer.

In some embodiments, the semiconductor device further includes an etch stop layer on the first layer.

In some embodiments: the duty cycle of each cycle of the corrugations differs by at most 0.7 from the duty cycle of an adjacent cycle of the corrugations, and the duty cycle of the cycle nearest the second region differs by at most 0.7 from the duty cycle of the second region.

In some embodiments, the duty cycles of the cycles of the corrugations follow, to within 0.2, a linear function of distance along the length of the device.

In some embodiments, the duty cycles of the cycles of the corrugations follow, to within 0.2, a piecewise linear function of distance along the length of the device.

In some embodiments, the duty cycles of the cycles of the corrugations follow, to within 0.2, a function of distance along the length of the device, the function having a continuous first derivative.

In some embodiments, the products of: the duty cycles and the corresponding fractional etch depths of the cycles of the corrugations follow, to within 0.2, a piecewise linear function of distance along the length of the device.

According to an embodiment of the present disclosure, there is provided a method for fabricating a semiconductor device, the method including: forming a first layer on a substrate; removing portions of the first layer; and forming a planarization layer on the first layer, the first layer having, after the removing of portions of the first layer, a first region and a second region, the first region being corrugated with a plurality of corrugations, the second region being uncorrugated, a first cycle of the corrugations having a first duty cycle, a second cycle of the corrugations having a second duty cycle, the second cycle being between the first cycle and the second region, the second duty cycle being between the first duty cycle and the duty cycle of the second region.

In some embodiments, the semiconductor device is a distributed feedback laser, the distributed feedback laser including: the first region of the first layer, and the second region of the first layer.

In some embodiments, the method further includes forming a plurality of quantum well layers on the substrate, after the forming the planarization layer.

In some embodiments, the method further includes forming a plurality of quantum well layers on the substrate, before the forming of the first layer.

In some embodiments, the method further includes forming an etch stop layer on the first layer.

In some embodiments: the duty cycle of each cycle of the corrugations differs by at most 0.7 from the duty cycle of an adjacent cycle of the corrugations, and the duty cycle of the cycle nearest the second region differs by at most 0.7 from the duty cycle of the second region.

In some embodiments, the duty cycles of the cycles of the corrugations follow, to within 0.2, a linear function of distance along the length of the device.

In some embodiments, the duty cycles of the cycles of the corrugations follow, to within 0.2, a piecewise constant function of distance along the length of the device.

In some embodiments, the duty cycles of the cycles of the corrugations follow, to within 0.2, a function of distance along the length of the device, the function having a continuous first derivative.

In some embodiments, the removing of portions of the first layer includes etching each of the portions to a respective etch depth.

In some embodiments, the products of: the duty cycles and the corresponding fractional etch depths of the cycles of the corrugations follow, to within 0.2, a linear function of distance along the length of the device.

### BRIEF DESCRIPTION OF THE DRAWINGS

These and other features and advantages of the present disclosure will be appreciated and understood with reference to the specification, claims, and appended drawings wherein:

FIG. 1 is a schematic end view of a semiconductor laser, according to an embodiment of the present disclosure;

FIG. 2 is a schematic side view of a related art semiconductor laser;

FIG. 3 is a schematic side view of a related art semiconductor laser, according to an embodiment of the present disclosure;

FIG. 4 is a schematic side view of a related art semiconductor laser, according to an embodiment of the present disclosure;

FIG. 5 is a schematic side view of a related art semiconductor laser, according to an embodiment of the present disclosure;

FIG. 6 is a schematic side view of a related art semiconductor laser, according to an embodiment of the present disclosure;

FIG. 7 is a schematic side view of a related art semiconductor laser, according to an embodiment of the present disclosure;

FIG. 8 is a schematic side view of a related art semiconductor laser, according to an embodiment of the present disclosure;

FIG. 9 is a schematic side view of a related art semiconductor laser, according to an embodiment of the present disclosure;

FIG. 10 is a schematic side view of a related art semiconductor laser, according to an embodiment of the present disclosure;

FIG. 11 is an intermediate product in the fabrication of a grating, according to an embodiment of the present disclosure;

FIG. 12A is an intermediate product in the fabrication of a grating, according to an embodiment of the present disclosure;

FIG. 12B is an intermediate product in the fabrication of a grating, according to an embodiment of the present disclosure;

FIG. 13A is an intermediate product in the fabrication of a grating, according to an embodiment of the present disclosure; and

FIG. 13B is an intermediate product in the fabrication of a grating, according to an embodiment of the present disclosure.

### DETAILED DESCRIPTION

The detailed description set forth below in connection with the appended drawings is intended as a description of exemplary embodiments of a DFB laser with reduced growth defects provided in accordance with the present disclosure and is not intended to represent the only forms in which the present disclosure may be constructed or utilized. The description sets forth the features of the present disclosure in connection with the illustrated embodiments. It is to be understood, however, that the same or equivalent functions and structures may be accomplished by different embodiments that are also intended to be encompassed within the scope of the disclosure. As denoted elsewhere herein, like element numbers are intended to indicate like elements or features.

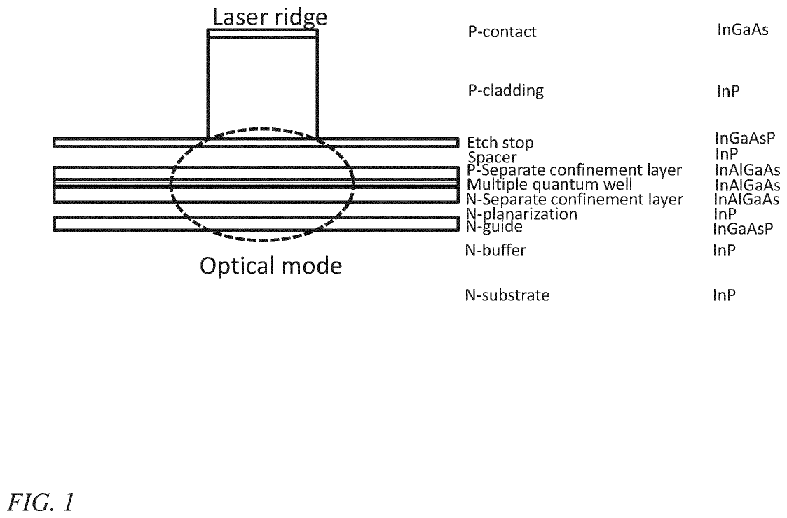

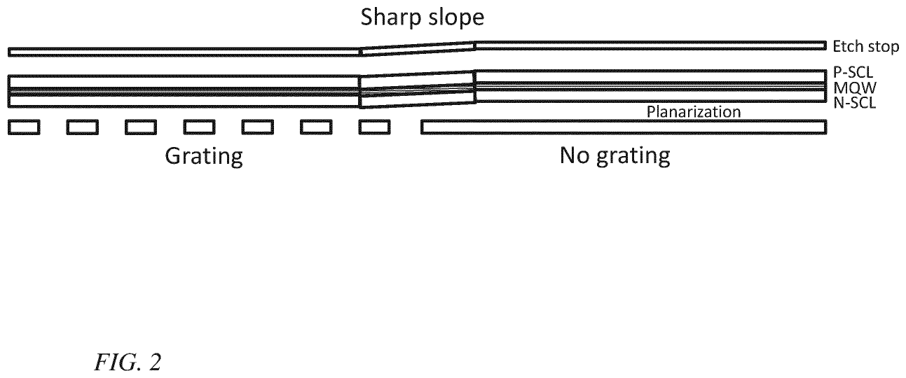

Referring to FIG. 1, in some embodiments, a distributed feedback (DFB) laser may include a substrate, a buffer layer on the substrate, a guide layer on the buffer layer, a planarization layer on the guide layer, a first separate confinement layer on the planarization layer, a plurality of quantum well (QW, or “multiple quantum well” (MQW)) layers on the first separate confinement layer, a second separate confinement layer on the plurality of quantum well layers, a spacer layer on the second separate confinement layer, an etch stop layer on the spacer layer, and a laser ridge on the etch stop layer. The DFB laser may be fabricated by growing the layers of the laser on the substrate with a process suitable for growing crystalline layers (e.g. metalorganic chemical vapor deposition (MOCVD)), with intervening etch steps. For example, as shown in FIG. 2, the guide layer may have gaps, or “trenches” etched into it (by a suitable lithographic process, as discussed in further detail below) forming a grating that may affect the behavior of the laser. The grating may extend along only a portion of the length of the laser as shown; such a structure may be referred to as a “partially corrugated” grating, and the portion of the guide layer within which the grating is formed may be referred to as the “corrugated portion” of the guide layer.

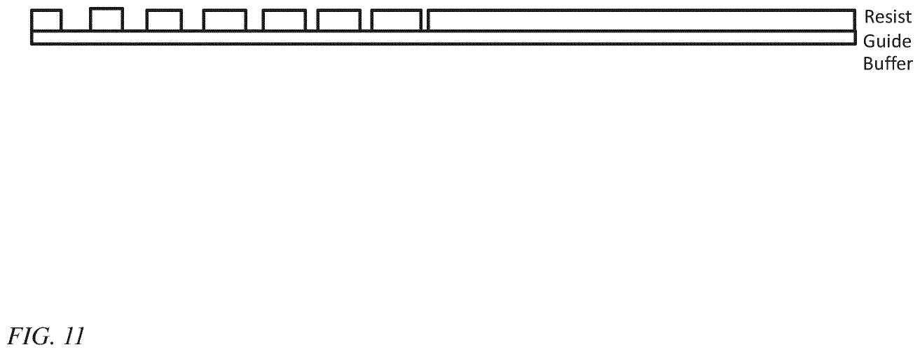

A partially corrugated grating may be formed by patterning and etching the guide layer (as discussed in further detail below, in the context of FIGS. 11-13B). After removal of portions of the guide layer, within the corrugated portion of the guide layer, the subsequent step in which the planarization layer is grown may result, as illustrated in FIG. 2, in the upper surface of the planarization layer being lower over the corrugated portion of the guide layer than over the intact portion of the guide layer, because some of the material deposited during the growth step is consumed to refill the gaps etched into the guide layer. If the uncorrugated portion of the guide layer is, instead of being undisturbed, entirely etched away, then the upper surface of the planarization layer may be higher over the corrugated portion of the guide layer than over the uncorrugated (fully etched away) portion of the guide layer. In either case, the height difference may result in the planarization layer having an upper surface that is not flat, and, in particular, that has a relatively steeply sloped surface (or “sharp slope”), surrounded by relatively abrupt changes in slope, which may cause a concentration of growth defects in the layers (including the quantum well layers) subsequently grown on the planarization layer.

In an illustrative example of a related-art DFB laser, the sharp slope occurs over a distance of 500˜1000 nm (along the length of the device) with a thickness change of 30 nm in the planarization layer. This produces a slope with an angle of between 1.7° and 3.4°. Epitaxial growth on a non-horizontal slope results in material having a different composition than material grown on a horizontal surface, and the inhomogeneity of the material composition in the sloped region may cause increased material stress and form growth defects in such a related-art DFB laser.

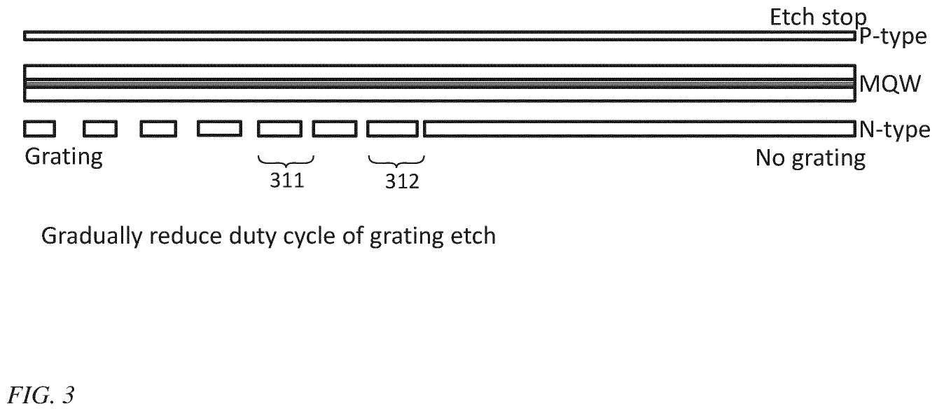

In some embodiments, the sharp slope in the planarization layer is made less steep (or less sharp) or eliminated. This may be achieved by gradually reducing the duty cycle of the corrugations, in a “transition region” of the guide layer between the “steady state” grating region (in which the grating may have a substantially constant duty cycle, e.g., a duty cycle of 0.5 (i.e., 50%)) and the no-grating region, as shown in FIG. 3. In some embodiments the duty cycle varies along the length of the device and the pitch of the grating (i.e., the separation between adjacent cycles of the corrugations) may remain constant along the length of the device. As used herein, the duty cycle of any cycle of the corrugations (i.e., of the corrugated portion of the guide layer) is the ratio of (i) the length (measured in the direction of propagation of light in the device) of the etched portion of the cycle (i.e., the portion that, in the completed device, has been refilled by the planarization layer) to (ii) the total length of the cycle. It may be seen that in FIG. 3, the guide layer includes a first region (the corrugated, or “grating” region) and a second region (the uncorrugated, or “no grating” region).

In the embodiment of FIG. 3, the duty cycle of the corrugations increases (in the transition region) with increasing distance from the second region. For example, a first cycle 311 has a first duty cycle, and a second cycle 312 has a second duty cycle, which may be seen FIG. 3 to be less than the first duty cycle. The unetched portion may be considered to have a duty cycle of 0 (as discussed in further detail below). As such, the second cycle is between the first cycle and the second region, and the second duty cycle is between the first duty cycle and the duty cycle of the second region.

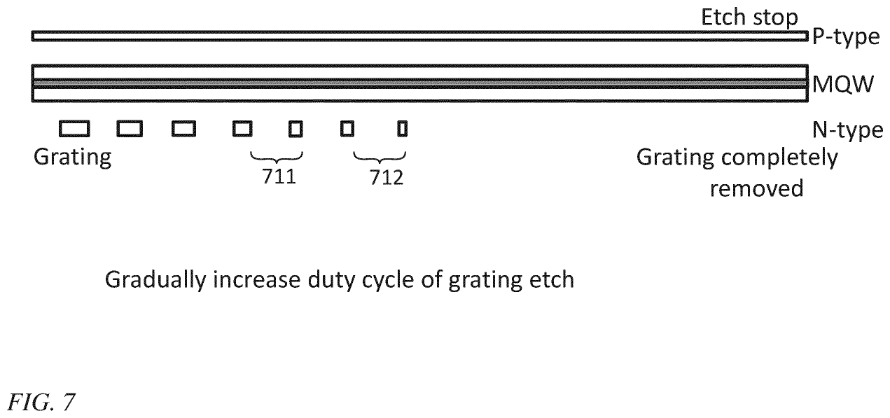

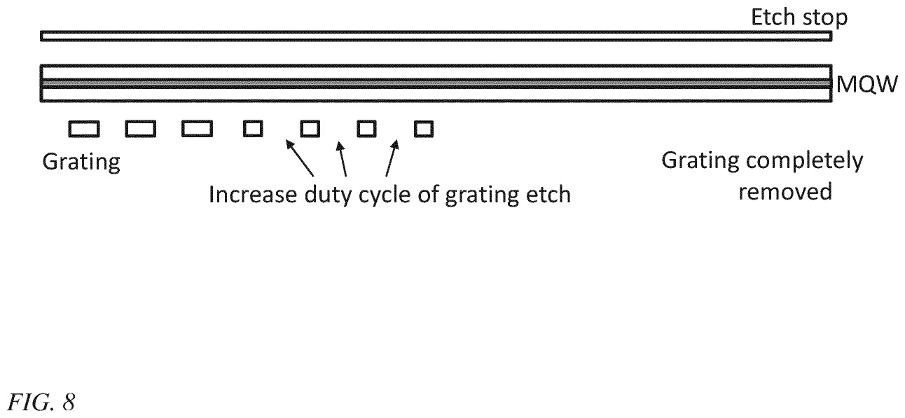

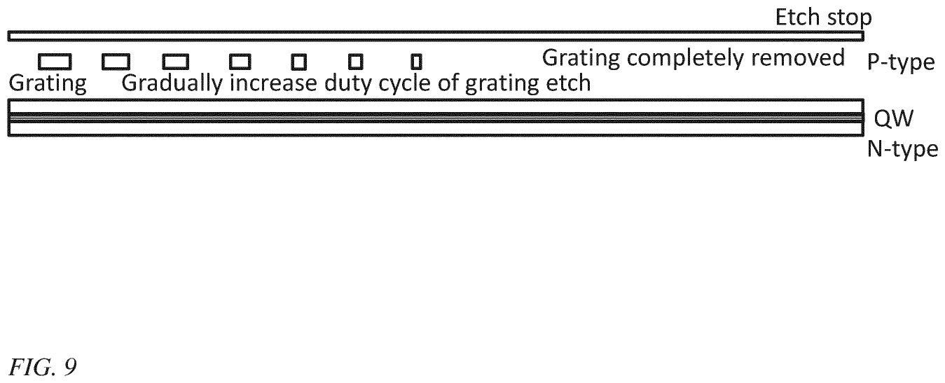

As used herein, the duty cycle of the guide layer is defined to be 0 (i.e., 0%) when the guide layer is unetched, and 1 (i.e., 100%) when the guide layer is etched (as shown for example, in the uncorrugated region, in FIGS. 7-9) (regardless of whether the etching step etches all the way through, or part-way through, the guide layer).

As an illustration of advantages of some embodiments, by gradually reducing the duty cycle over a distance of 6 um, the slope (for the same thickness change of 30 nm) is reduced to 0.3°. This angle is comparable to the typical angular tolerance of the starting substrate material (for example +/−0.3°) and may produce at most an inconsequential change in material composition that does not cause growth defects.

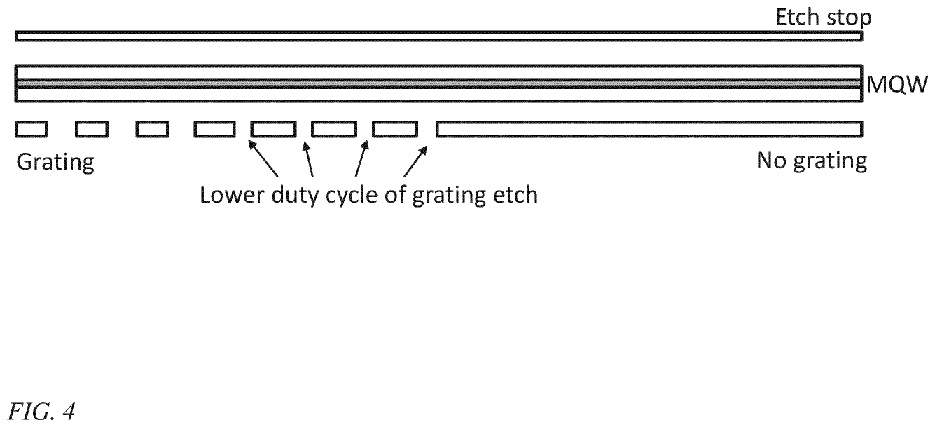

In another embodiment, the etched region is changed to one or more intermediate duty cycles between the no-grating region and the steady state region, as shown in FIG. 4. As an illustration, by changing the duty cycles in 2 steps over a distance of 6 um, with a thickness change of 10 nm at each step, the slope is again reduced to 0.3° and, in this embodiment too, the resulting slope may produce at most an inconsequential change in material composition that does not cause growth defects. In this embodiment, the duty cycle is a piecewise constant function of distance along the length of the device. As used herein, when a quantity is described as varying according to a certain function of distance “along the length of the device” it means that the functions is a function of distance along the length of the device (as opposed to distance along another direction), over a portion of the length of the device (a portion which may be less than the entire length of the device); it does not mean that the quantity varies according to the function along the entire length of the device.

In some embodiments the duty cycle is a piecewise linear function of distance along the length of the device (e.g., changing linearly from a constant value of 50% in a first region (the steady state region) to a constant value of 0% (in the uncorrugated region) (or to a constant value of 100% as illustrated in some embodiments described below). In some embodiments the duty cycle is another function of distance along the length of the device, e.g., a function having a piecewise linear (i.e., continuous) first derivative or a piecewise linear second derivative.

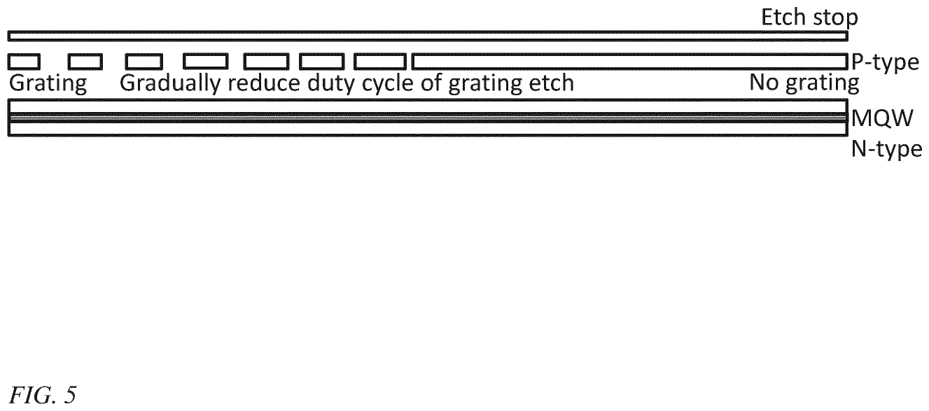

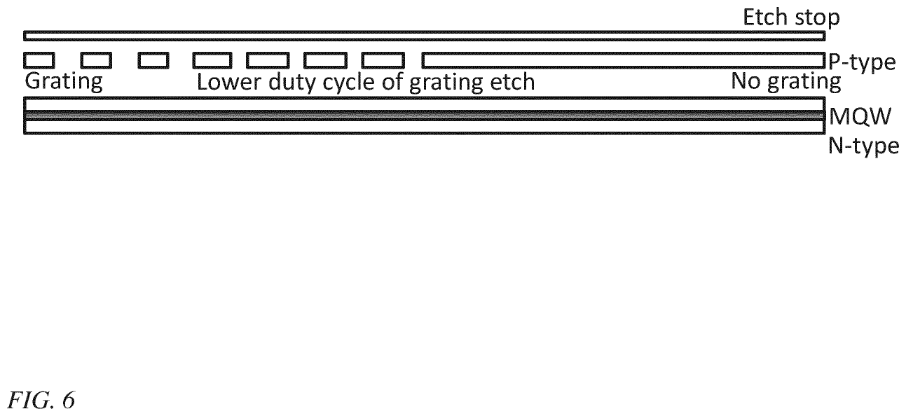

In addition to eliminating growth defects that affect the quantum well active region in an n-side grating DFB laser, in some embodiments, the fabrication quality and yield of DFB lasers with p-side gratings are improved. In a DFB laser with a p-side grating, the quantum well active region may be unaffected by the presence of growth defects caused by a sharp slope in the top surface of the planarization layer. However, these growth defects may become weak spots in the etch stop layer that separates the laser ridge and the underlying quantum well active region. The presence of weak spots in the etch stop layer may results in localized etch-through pits that degrade laser performance and affect the yield. Corresponding embodiments for a DFB laser with a p-side grating are shown in FIG. 5 and FIG. 6.

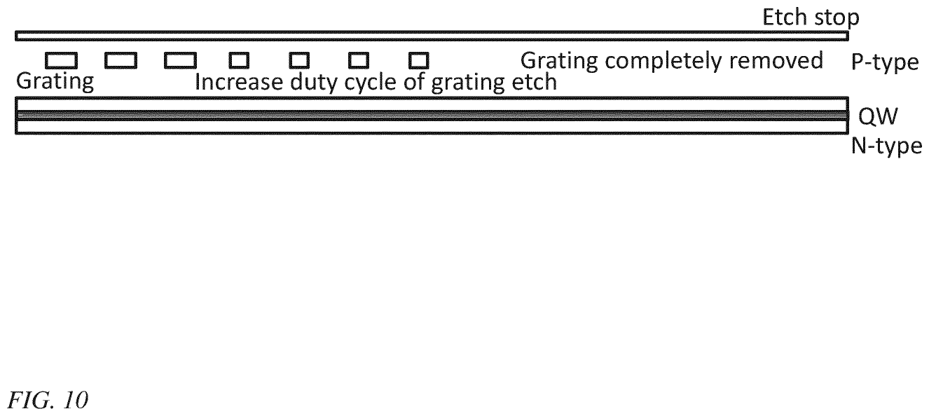

In the embodiments shown in FIGS. 3, 4, 5, and 6, the guide layer in the no-grating region is intact. By contrast, in FIGS. 7, 8, 9, and 10, the guide layer in the no-grating region is completely removed. These alternative embodiments eliminate the sharp slope in planarization by gradually increasing the duty cycle of the etched region (or increasing it step-wise, over multiple steps) from the steady state region to the no-grating region.

For example, in the embodiment of FIG. 7, the duty cycle of the corrugations decreases (in the transition region) with increasing distance from the second region (the second region being the uncorrugated, no-grating region). For example, a first cycle 711 has a first duty cycle, and a second cycle 712 has a second duty cycle, which may be seen in FIG. 7 to be greater than the first duty cycle. The unetched portion may be considered to have a duty cycle of 1 (as mentioned above). As such (as is the case in the embodiment of FIG. 3), the second cycle is between the first cycle and the second region, and the second duty cycle is between the first duty cycle and the duty cycle of the second region.

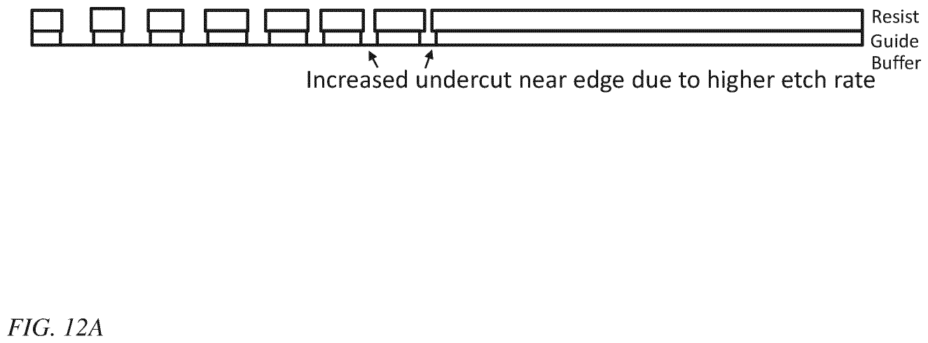

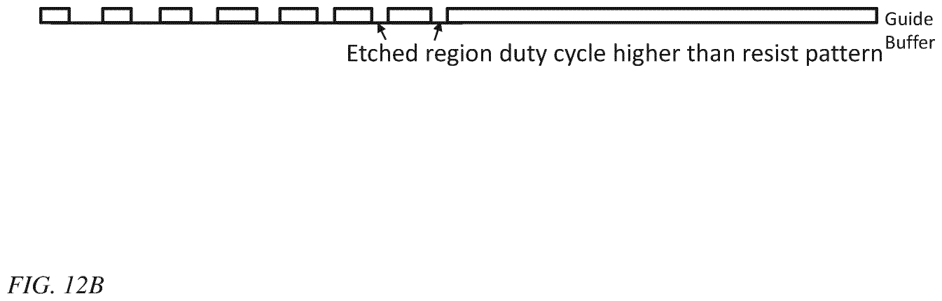

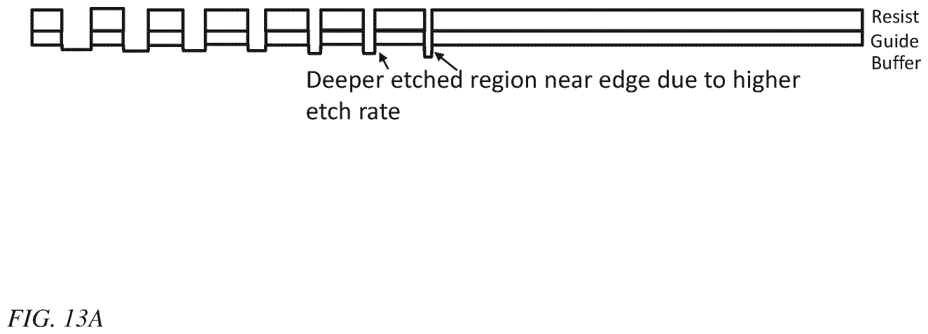

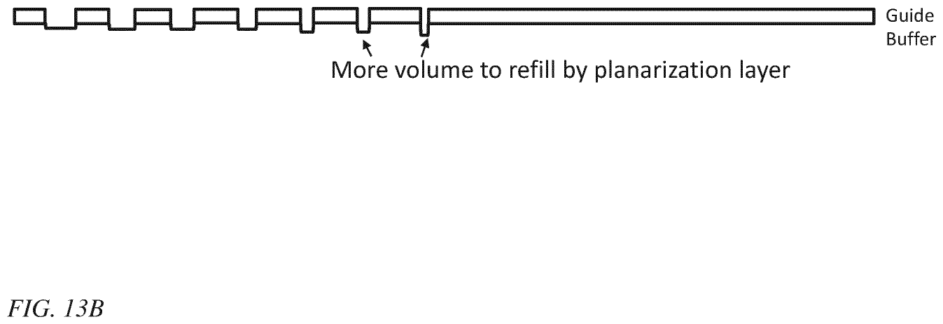

FIGS. 11-13B show intermediate products in the fabrication of a grating, using a wet etch (FIGS. 11, 12A, and 12B) or a dry etch (FIGS. 11, 13A, and 13B). In FIG. 11, the resist has been patterned. In FIGS. 12A and 12B, the guide layer has been etched, and in FIGS. 12B and 13B, the resist has been stripped away.

The change in duty cycle of the etched regions can be achieved by changing the patterning resist defining the etch, shown for example in FIG. 11. This patterning resist can be defined by e-beam lithography or other suitable patterning means known in the art, such as holographic UV light exposure. For etched regions formed by a wet etching process, the patterning resist may be patterned with a pattern that has a different duty cycle (e.g., a lower duty cycle, as a function of distance along the length of the device) than the target duty cycle of the etched regions, as shown in FIGS. 12A and 12B. Such a pattern in the patterning resist may compensate for the property of wet etching that the undercutting rate is enhanced at the edge of an etched region next to a region with no etching due to loading effects.

For etched regions formed by a dry etching process, a patterning resist that has a more complex duty cycle profile may be employed, to compensate for the property of dry etching that enhances the etch rate at the edge of an etched region next to a region with no etching due to loading effects. The deeper etch near the edge of the etched region may require more refill from the planarization layer and result in increased slope on the planarization layer, as shown in FIGS. 13A and 13B. The fact that the narrower, deeper trenches may need more refill material during the forming of the planarization layer (than they would if the depths of the trenches were all equal) may be compensated for by using a patterning resist pattern having a non-linearly varying duty cycle (e.g., one in which the products of the duty cycles and the expected corresponding etch depths follow a target function (e.g., a linear function), or one in which the first derivative of the duty cycle increases with increasing duty cycle) that takes into account the effects of both the trench width and depth on the actual refill volume. In some embodiments, the need to compensate for variations in trench depth may be reduced or eliminated by using a dry etch process tuned to minimize loading effects.

In some embodiments the guide layer may be partially etched, i.e., the etching steps of FIGS. 12A and 13A may etch only part way through the guide layer, instead of etching all the way through the guide layer as shown in FIGS. 12A and 13A. In some embodiments, the depths of the trenches may vary within the transition region, in addition to, or instead of, the duty cycle varying. Such a structure may be fabricated, for example, using a dry etch process that also etches the resist material. A shallow set of corrugations in the resist pattern may then translate into a shallow set of trenches in the guide layer, (resulting, for example, in a partially etched guide layer). Shallow corrugations may be formed by intentionally reducing the exposure dosage of the resist pattern. In this case the resist pattern would not be “digital” as shown in FIGS. 11, 12A, and 13A, and may instead have corrugations of varying depth. As used herein, the “fractional etch depth” is the ratio of the depth of the trenches to the thickness of the guide layer. The same definition is employed if the trench depth exceeds the thickness of the guide layer, so that, for example, in FIGS. 13A and 13B, the fractional etch depth is greater than 1.

Although some embodiments herein are described in the context of a DFB laser, the invention is not limited to DFB lasers, and may, for example, be used with other semiconductor devices such as DBR (distributed Bragg reflector) lasers (which may also contain sections with gratings and sections without gratings), and sampled grating DBR lasers (which may contain multiple grating sections with different pitches, and non-grating sections). Where a certain functional form is described herein for, e.g., the variation of the duty cycle, or of the fractional etch depth, or of the product of the duty cycle and the fractional etch depth, as a function of distance along the length of the device, it will be understood that because of fabrication tolerances the characteristics of an actual device may not follow the function exactly, but may instead follow it to within 0.1, or to within 0.2, or to within 0.3, or to within 0.4, or to within 0.5, or to within 0.6 or to within 0.7, or to within 0.8, or to within 0.9. In some devices, the duty cycle (or the fractional etch depth, or the product of the duty cycle and the fractional etch depth) of each cycle of the corrugations differs by at most 0.9 (or at most 0.8, or at most 0.7, or at most 0.6, or at most 0.5, or at most 0.4, or at most 0.3, or at most 0.2, or at most 0.1) from the corresponding characteristic of an adjacent cycle of the corrugations, and the duty cycle (or the fractional etch depth, or the product of duty cycle and fractional etch depth) of the cycle nearest the second region (i.e., the uncorrugated region) differs by at most 0.9 (or at most 0.8, or at most 0.7, or at most 0.6, or at most 0.5, or at most 0.4, or at most 0.3, or at most 0.2, or at most 0.1) from the duty cycle of the second region. In some embodiments, the region shown as uncorrugated in the drawings (the second region) is (instead of being entirely uncorrugated) corrugated, with a different fractional etch depth, or with a different duty cycle, than the steady state region.

As used herein, for a device within which light propagates in operation, a “corrugated” region in a layer of the device means a region having alternating etched and unetched portions (each combination of an etched portion and an adjacent unetched portion being a “cycle” of the corrugations) along the length of the device, the length direction being the direction of propagation of light in operation, the total length (in the direction of propagation of light in the device) of any etched portion and the adjacent unetched portion on either side being at most 3 microns. As used herein, “uncorrugated” means not corrugated. As used herein, when a characteristic (e.g., the duty cycle) of the corrugations “follows”, to within a certain amount, a certain function, it means that the absolute value of the difference between the characteristic and the function is less than the amount, for each cycle of the corrugations. As used herein, when a first number is “between” a second number and a third number it means that (i) the first number is greater than the second number and less than the third number or (ii) the first number is less than the second number and greater than the third number. As used herein, when a first number “differs by at most” an amount from a second number it means that the absolute value of the difference between the first number and the second number is less than or equal to the amount.

It will be understood that when an element or layer is referred to as being “on”, “under”, or “adjacent to” another element or layer, it may be directly on, under, or adjacent to the other element or layer, or one or more intervening elements or layers may be present. In contrast, when an element or layer is referred to as being “directly on”, “directly under”, or “immediately adjacent to” another element or layer, there are no intervening elements or layers present. As used herein, “a portion of” something means all, or less than all, of the thing. As used herein, the terms “on” and “under” are used assuming an orientation of the device in which the substrate is at the bottom of the device. As used herein, the word “or” is inclusive, so that, for example, “A or B” means any one of (i) A, (ii) B, and (iii) A and B.

Although exemplary embodiments of a DFB laser with reduced growth defects have been specifically described and illustrated herein, many modifications and variations will be apparent to those skilled in the art. Accordingly, it is to be understood that a DFB laser with reduced growth defects constructed according to principles of this disclosure may be embodied other than as specifically described herein. The invention is also defined in the following claims, and equivalents thereof.

1. A semiconductor device, comprising:
a first layer having a first region and a second region,
the first region being corrugated with a plurality of corrugations,
the second region being uncorrugated,
a first cycle of the corrugations having a first duty cycle,
a second cycle of the corrugations having a second duty cycle,
the second cycle being between the first cycle and the second region, and
the second duty cycle being between the first duty cycle and the duty cycle of the second region.

2. The semiconductor device of claim 1, comprising a distributed feedback laser, the distributed feedback laser comprising:
the first region of the first layer, and
the second region of the first layer.

3. The semiconductor device of claim 1, further comprising a plurality of quantum well layers on the first layer.

4. The semiconductor device of claim 1, further comprising a plurality of quantum well layers under the first layer.

5. The semiconductor device of claim 1, further comprising an etch stop layer on the first layer.

6. The semiconductor device of claim 1, wherein:
the duty cycle of each cycle of the corrugations differs by at most 0.7 from the duty cycle of an adjacent cycle of the corrugations, and
the duty cycle of the cycle nearest the second region differs by at most 0.7 from the duty cycle of the second region.

7. The semiconductor device of claim 1, wherein the duty cycles of the cycles of the corrugations follow, to within 0.2, a piecewise linear function of distance along the length of the device.

8. The semiconductor device of claim 1, wherein the duty cycles of the cycles of the corrugations follow, to within 0.2, a piecewise constant function of distance along the length of the device.

9. The semiconductor device of claim 1, wherein the duty cycles of the cycles of the corrugations follow, to within 0.2, a function of distance along the length of the device, the function having a continuous first derivative.

10. The semiconductor device of claim 1, wherein the products of:
the duty cycles and
the corresponding fractional etch depths
of the cycles of the corrugations follow, to within 0.2, a piecewise linear function of distance along the length of the device.

11. A method for fabricating a semiconductor device, the method comprising:
forming a first layer on a substrate;
removing portions of the first layer; and
forming a planarization layer on the first layer,
the first layer having, after the removing of portions of the first layer, a first region and a second region,
the first region being corrugated with a plurality of corrugations,
the second region being uncorrugated,
a first cycle of the corrugations having a first duty cycle,
a second cycle of the corrugations having a second duty cycle,
the second cycle being between the first cycle and the second region, and
the second duty cycle being between the first duty cycle and the duty cycle of the second region.

12. The method of claim 11, wherein the semiconductor device is a distributed feedback laser, the distributed feedback laser comprising:
the first region of the first layer, and
the second region of the first layer.

13. The method of claim 11, further comprising forming a plurality of quantum well layers on the substrate, after the forming the planarization layer.

14. The method of claim 11, further comprising forming a plurality of quantum well layers on the substrate, before the forming of the first layer.

15. The method of claim 11, further comprising forming an etch stop layer on the first layer.

16. The method of claim 11, wherein:
the duty cycle of each cycle of the corrugations differs by at most 0.7 from the duty cycle of an adjacent cycle of the corrugations, and
the duty cycle of the cycle nearest the second region differs by at most 0.7 from the duty cycle of the second region.

17. The method of claim 11, wherein the duty cycles of the cycles of the corrugations follow, to within 0.2, a piecewise linear function of distance along the length of the device.

18. The method of claim 11, wherein the duty cycles of the cycles of the corrugations follow, to within 0.2, a piecewise constant function of distance along the length of the device.

19. The method of claim 11, wherein the duty cycles of the cycles of the corrugations follow, to within 0.2, a function of distance along the length of the device, the function having a continuous first derivative.

20. The method of claim 11, wherein the removing of portions of the first layer comprises etching each of the portions to a respective etch depth.

21. The method of claim 20, wherein the products of:
the duty cycles and
the corresponding fractional etch depths
of the cycles of the corrugations follow, to within 0.2, a piecewise linear function of distance along the length of the device.
